(19) United States
(12) Patent Application Publication
(10) Pub. No.: US 2025/0176205 A1
(43) Pub. Date: May 29, 2025

(54) SEMICONDUCTOR STRUCTURE

(71) Applicant: Taiwan-Asia Semiconductor Corporation, Hsinchu City (TW)

(72) Inventors: Jui-Lun CHUNG, Hsinchu City (TW); Sheng-Ping WANG, Hsinchu City (TW)

(21) Appl. No.: 18/816,782

(22) Filed: Aug. 27, 2024

(30) Foreign Application Priority Data
Nov. 28, 2023 (TW) 112146161

(51) Int. Cl. H01L 29/778; H01L 29/49; H01L 29/66

(52) U.S. Cl. CPC H10D 30/475; H10D 64/667; H10D 30/015

(57) ABSTRACT

A semiconductor structure is provided. The semiconductor structure includes a substrate, a semiconductor barrier layer and a gate electrode. The semiconductor barrier layer is disposed above the substrate. The gate electrode is disposed above the semiconductor barrier layer and has a first gate barrier layer and a second gate barrier layer. The first gate barrier layer is disposed between the semiconductor barrier layer and the second gate barrier layer. The work function of the first gate barrier layer is greater than that of the semiconductor barrier layer, and the work function of the second gate barrier layer is greater than that of the first gate barrier layer.

### CROSS-REFERENCES TO RELATED APPLICATIONS

This application claims the benefit of priority to Taiwanese Patent application Ser. No. 112146161 filed on Nov. 28, 2023, which is hereby incorporated by reference in its entirety.

### BACKGROUND OF THE INVENTION

### Field of the Invention

The present invention relates to a semiconductor structure, in particular to a high electron mobility transistor.

### Descriptions of the Related Art

In recent years, due to the increasing demand for high-frequency and high-power products, semiconductor power devices using gallium nitride materials, such as aluminum gallium nitride/gallium nitride (AlGaN/GaN), have wide energy gaps and high-speed mobile electrons to achieve high switching speeds. Moreover, semiconductor power devices have characteristics that can be operated in high-frequency, high-power and high-temperature working environments so they can be widely used in high-power semiconductor structures, especially in applications of radio frequency devices and power devices. Traditionally, high electron mobility transistors use group III-V semiconductor stacks to form heterojunctions at their interfaces. Due to the energy band bending at the heterojunction, a potential well is formed deep in the bend of the conduction band, and a two-dimensional electron gas (2DEG) is formed in the potential well.

Generally speaking, a high electron mobility transistor is a normally-on (D-mode: Normally-on) device, or a depletion mode device, which requires an additional negative bias voltage to turn off the device. In addition to being relatively inconvenient to use, it also limits the use scope of the devices. On the other hand, another enhancement-mode high electron mobility transistor is currently proposed. A normally-off (E-mode: Normally-off) device can be achieved by using fluorine ion bombardment to destroy the lattice structure of the aluminum gallium nitride layer before forming the metal gate, or by etching the aluminum gallium nitride layer to form recesses therein, or by using the gate stack structure of the gallium nitride layer with P-type impurities. The E-mode device that can turn off the two-dimensional electron gas without applying additional bias voltage.

However, the gate source driving voltage (Vgs) of the currently common E-mode gallium nitride high electron mobility transistor is between 7V and 10V. The gate hard breakdown occurs due to the high gate leakage current so the operation range will be limited to 0V to 6V. On the other hand, the gate leakage of common D-mode gallium nitride high electron mobility transistor is relatively high, even reaching the milliampere level, the gate leakage current will also increase during the process of increasing the gate voltage when operating the above devices. However, an increase in gate leakage current may lead to device failure, so it is necessary to effectively control the gate leakage current thereof. In order to overcome the above problems, the industry is in urgent need of an innovative semiconductor structure to improve the above-mentioned problem of possible device failure caused by gate leakage currents.

### SUMMARY OF THE INVENTION

The main objective of the present invention is to provide an innovative semiconductor structure that increases the voltage operation range of the device by increasing the gate collapse voltage. By this way, the problems of device failure caused by the high gate leakage current of conventional high electron mobility transistor can be correspondingly improved.

To achieve the above objective, the present invention discloses a semiconductor structure which includes a substrate, a semiconductor barrier layer and a gate electrode. The semiconductor barrier layer is disposed above the substrate. The gate electrode is disposed above the semiconductor barrier layer and has a first gate barrier layer and a second gate barrier layer. The first gate barrier layer is disposed between the semiconductor barrier layer and the second gate barrier layer. The work function of the first gate barrier layer is greater than that of the semiconductor barrier layer, and the work function of the second gate barrier layer is greater than that of the first gate barrier layer.

In one embodiment of the semiconductor structure of the present invention, the first gate barrier layer is a conductive metal compound, and a work function of the conductive metal compound is not less than 4 eV.

In one embodiment of the semiconductor structure of the present invention, the conductive metal compound is selected from the group consisting of titanium nitride, tantalum nitride, and tungsten nitride.

In one embodiment of the semiconductor structure of the present invention, the second gate barrier layer is a conductive material, and a work function of the conductive material is not less than 5 eV.

In one embodiment of the semiconductor structure of the present invention, the conductive material is selected from the group consisting of nickel, platinum, tungsten, and tungsten nitride.

In one embodiment of the semiconductor structure of the present invention, the semiconductor structure further comprises a source electrode and a drain electrode, respectively disposed above the semiconductor barrier layer.

In one embodiment of the semiconductor structure of the present invention, the source electrode and the drain electrode are selected from the group consisting of titanium, aluminum, nickel, molybdenum, titanium nitride, gold and their combinations

In one embodiment of the semiconductor structure of the present invention, the semiconductor barrier layer is an aluminum gallium nitride layer.

In one embodiment of the semiconductor structure of the present invention, the semiconductor structure further comprises a gallium nitride layer, wherein the aluminum gallium nitride layer is disposed above the gallium nitride layer.

In one embodiment of the semiconductor structure of the present invention, the semiconductor structure further comprises a P-type doped gallium nitride layer, wherein the P-type doped gallium nitride layer is disposed between the aluminum gallium nitride layer and the first gate barrier layer, and the work function of the first gate barrier layer is greater than a work function of the P-type doped gallium nitride layer.

In one embodiment of the semiconductor structure of the present invention, the semiconductor barrier layer below the gate electrode further includes a recessed structure, and the recessed structure is filled with the first gate barrier layer

In one embodiment of the semiconductor structure of the present invention, a portion of the aluminum gallium nitride layer below the gate electrode is doped by fluorine ions.

In one embodiment of the semiconductor structure of the present invention, the gate electrode further comprises a low-resistance metal layer, disposed above the second gate barrier layer.

In one embodiment of the semiconductor structure of the present invention, the low-resistance metal layer is selected from the group consisting of aluminum, platinum, titanium, nickel, tungsten, copper, palladium, gold and their combinations.

To achieve the above objective, the present invention discloses a semiconductor structure which comprises a substrate, a semiconductor barrier layer, an anode electrode and a cathode electrode. The semiconductor barrier layer is disposed above the substrate. The anode electrode and the cathode electrode are respectively disposed at two opposite ends above the semiconductor barrier layer. The anode electrode has a first anode barrier layer and a second anode barrier layer. The first anode barrier layer is disposed between the semiconductor barrier layer and the second anode barrier layer. A work function of the first anode barrier layer is greater than that of the semiconductor barrier layer, and a work function of the second anode barrier layer is greater than that of the first anode barrier layers.

In one embodiment of the semiconductor structure of the present invention, the first anode barrier layer is a conductive metal compound, and a work function of the conductive metal compound is not less than 4 eV.

In one embodiment of the semiconductor structure of the present invention, the conductive metal compound is selected from the group consisting of titanium nitride, tantalum nitride, and tungsten nitride.

In one embodiment of the semiconductor structure of the present invention, the second anode barrier layer is a conductive material, and a work function of the conductive material is not less than 5 eV.

In one embodiment of the semiconductor structure of the present invention, the conductive material is selected from the group consisting of nickel, platinum, tungsten, and tungsten nitride.

In one embodiment of the semiconductor structure of the present invention, the semiconductor barrier layer is an aluminum gallium nitride layer, and the semiconductor structure further comprises a P-type doped gallium nitride layer, disposed between the aluminum gallium nitride layer and the first anode barrier layer, and the work function of the first anode barrier layer is greater than a work function of the P-type doped gallium nitride layer.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 to FIG. 5 are schematic diagrams illustrating steps of manufacturing process of a normally-on high electron mobility transistor in an embodiment of the present invention;

FIG. 6 is a comparison curve diagram of gate current and voltage relationship between the normally-on high electron mobility transistor of the present invention and the conventional normally-on high electron mobility transistor;

FIG. 7 to FIG. 12 are schematic diagrams illustrating steps of manufacturing process of a normally-off high electron mobility transistor in an embodiment of the present invention;

FIG. 13 is a comparison curve diagram of gate current and voltage relationship between the normally-off high electron mobility transistor of the present invention and the conventional normally-off high electron mobility transistor;

FIG. 14 is a schematic diagram of a normally-off high electron mobility transistor with a recessed gate structure in an embodiment of the present invention;

FIG. 15 is a schematic diagram of a normally-off high electron mobility transistor with fluorine ion dopants in an embodiment of the present invention;

FIG. 16 is a schematic diagram of a normally-on Schottky barrier diode in an embodiment of the present invention; and

FIG. 17 is a schematic diagram of a normally-off Schottky barrier diode in an embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

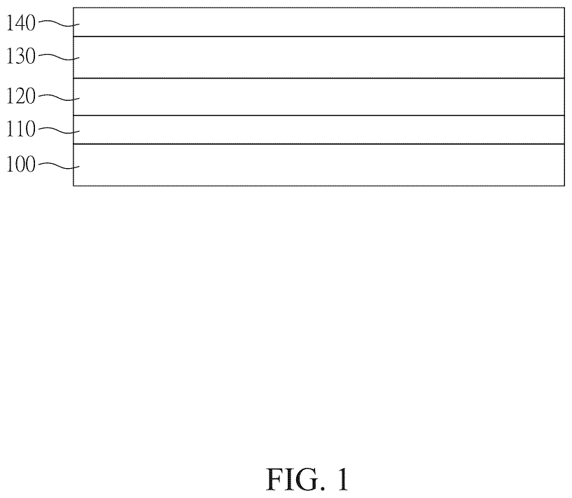

Referring to FIG. 1, it illustrates a semiconductor structure and a manufacturing method thereof in an embodiment of the present invention, particularly a normally-on or depletion mode (D-Mode) high electron mobility transistor and its manufacturing method. A nucleation layer 110, a buffer layer 120, a channel layer 130, and a semiconductor barrier layer 140 are formed on a substrate 100 sequentially. The material of the substrate 100 may include silicon, sapphire, diamond, gallium nitride, silicon carbide, gallium arsenide, etc. The nucleation layer 110 is disposed above the substrate 100 with a thickness of tens to hundreds of nanometers, used to reduce the lattice mismatch between the substrate 100 and the semiconductor barrier layer 140. The nucleation layer 110, for example, is composed of a group III-V material, including aluminum nitride, gallium nitride, or aluminum gallium nitride. The buffer layer 120 is disposed above the nucleation layer 110 with a thickness of several micrometers to tens of micrometers. It can also be made of a group III-V material, used to reduce the lattice mismatch between the substrate 100 and the semiconductor barrier layer 140, and to reduce lattice defects. In this embodiment, the buffer layer 120 may include a single-layer structure or a multilayer structure, such as a super lattice multilayer or a single-layer III-V semiconductor material, such as aluminum nitride, gallium nitride, or aluminum gallium nitride.

The channel layer 130 is formed on the buffer layer 120 and has a first energy gap. The semiconductor barrier layer 140 is formed on the channel layer 130 and has a second energy gap which is higher than the first energy gap. The lattice constant of the semiconductor barrier layer 140 is smaller than that of the channel layer 130. In this embodiment, the materials of the channel layer 130 and the semiconductor barrier layer 140 include aluminum indium gallium nitride (AlₓIn_{y}Ga_{(1-x-y)}N), where 0≤x<1, and 0≤x+y≤1. In this embodiment, the channel layer 130 may be a gallium nitride layer, while the semiconductor barrier layer 140 may be an aluminum gallium nitride layer or an indium gallium nitride layer. Due to the spontaneous polarization and the piezoelectric polarization between the channel layer 130 and the semiconductor barrier layer 140, a two-dimensional electron gas (2DEG) is generated at the heterojunction between the channel layer 130 and the semiconductor barrier layer 140.

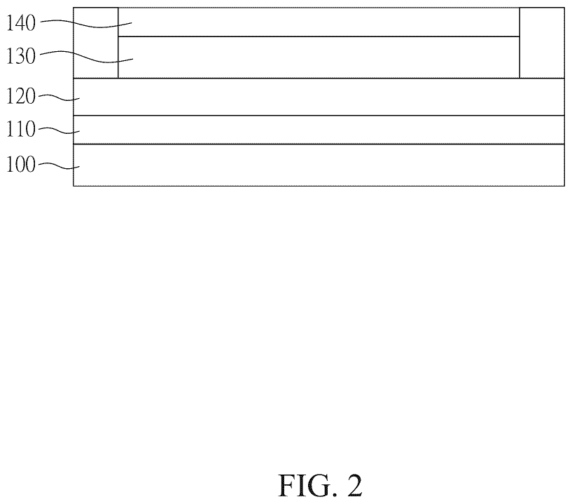

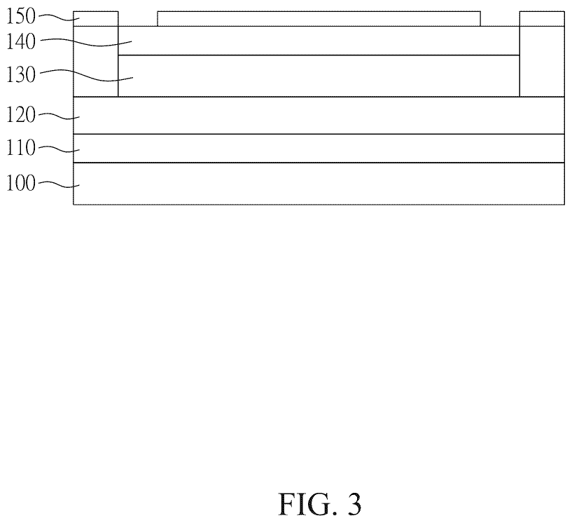

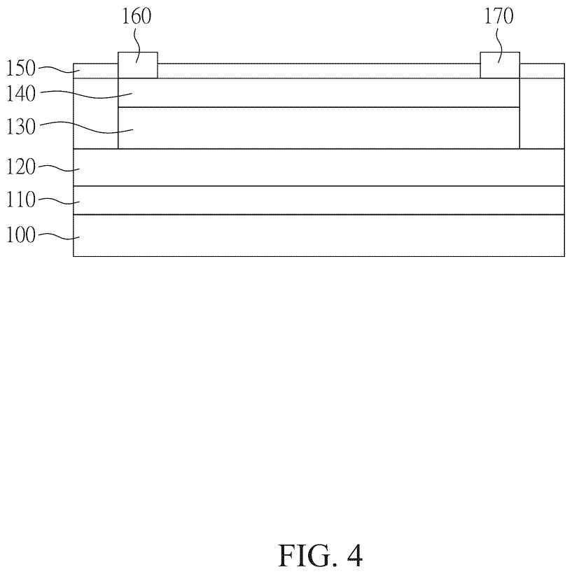

Referring to FIG. 2, an isolation insulation process between the active region and the non-active region of the device can be implemented. For example, a MESA etching process or an ion implantation process can be performed. In this embodiment, ion implantation using, such as nitrogen ions, argon ions, boron ions, oxygen ions, and arsenic ions can be performed to achieve device isolation. Referring to FIG. 3, an insulation protective layer 150 is then deposited on the substrate for defining the source and drain regions. The insulation protective layer 150 can be made of materials such as silicon nitride, aluminum nitride, aluminum oxide, silicon dioxide, silicon oxynitride, silicon carbide, etc. Referring to FIG. 4, the source electrode 160 and the drain electrode 170 forming ohmic contacts with the semiconductor barrier layer 140 are formed on the source and drain regions above the semiconductor barrier layer 140. Specifically, the source electrode and the drain electrode are alloy materials formed on the aluminum gallium nitride layer through a metal evaporation process. The alloy material can form ohmic contact with the aluminum gallium nitride layer at high temperatures. The alloy materials can be selected from the group consisting of titanium, aluminum, nickel, molybdenum, titanium nitride, gold, and their combinations. More specifically, the source and drain electrodes can be metal alloy systems such as titanium/aluminum/nickel/gold alloys, titanium/aluminum/titanium/gold alloys, titanium/aluminum/molybdenum/gold alloys, titanium/aluminum/titanium/titanium nitride alloys, and so on.

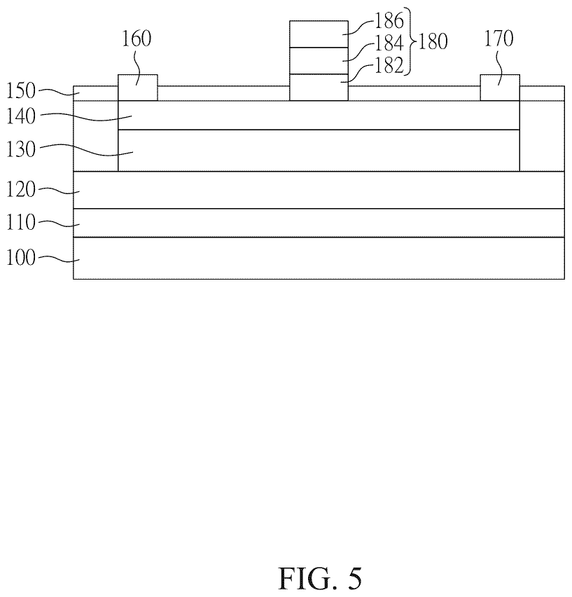

Referring to FIG. 5, expose a portion of the semiconductor barrier layer 140 to define the gate electrode region on the insulation protective layer 150. A metal evaporation process is then performed in this gate electrode region to form a gate electrode 180 above the exposed portion of the semiconductor barrier layer 140. To solve the problem of gate hard breakdown caused by high gate leakage current in conventional high electron mobility transistor devices, the present invention discloses an innovative gate structure with dual barrier layers to suppress gate leakage current. Specifically, the gate electrode 180 of the present invention includes a first gate barrier layer 182 and a second gate barrier layer 184. The first gate barrier layer 182 is disposed above the exposed portion of the semiconductor barrier layer 140, while the second gate barrier layer 184 is disposed above the first gate barrier layer 182. Particularly, the work function of the first gate barrier layer 182 is greater than that of the semiconductor barrier layer 140, and the work function of the second gate barrier layer 184 is greater than that of the first gate barrier layer 182. In specific embodiments, the first gate barrier layer 182 can be a conductive metal compound or a conductive ceramic, with a work function not less than 4 eV, but not limited thereto. The conductive metal compound is selected from the group consisting of titanium nitride, tantalum nitride, and tungsten nitride. The second gate barrier layer 184 can be a conductive material with a higher work function not less than 5 eV, but not limited thereto. The conductive material is selected from the group consisting of nickel, platinum, tungsten, and tungsten nitride. Additionally, the gate electrode 180 further includes a low-resistance metal layer 186 disposed above the second gate barrier layer 184. The low-resistance metal layer is selected from the group consisting of aluminum, platinum, titanium, nickel, tungsten, copper, palladium, gold, and their combinations.

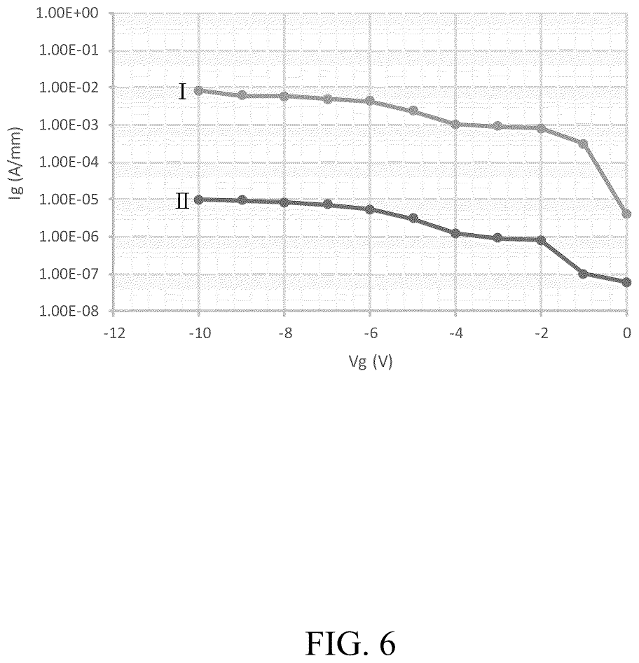

Please refer to FIG. 6, which illustrates a comparison curve of the gate current versus voltage relationship between the D-mode high electron mobility transistor (HEMT) of the present invention and a conventional D-mode HEMT device. In FIG. 6, curve I represents the current-voltage curve of the conventional D-mode HEMT device, while curve II represents the current-voltage curve of the D-mode HEMT device of the present invention. Comparing the current-voltage curves I and II in FIG. 6, it can be observed that the gate leakage current of the conventional D-mode HEMT device is relatively high, approximately ranging from 1.00E-02 to 1.00E-03 amperes. In contrast, the difference in work functions of the dual gate barrier layers is used to significantly suppress the gate leakage current of the D-mode HEMT device of the present invention. Specifically, the gate leakage current of the D-mode HEMT device of the present invention can be reduced by approximately 1000 times to a range of 1.00E-05 to 1.00E-07 amperes.

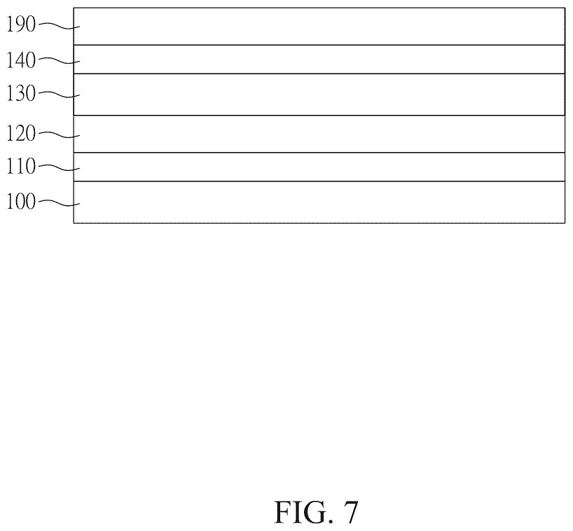

It should be noted that the above contents only represent one of the embodiments of the present invention which a normally-on or depletion-mode high electron mobility transistor (HEMT) is utilized. In fact, those skilled in the art can utilize the technical features of the present invention, which discloses a dual barrier layer gate structure, to extend its application to normally-off high electron mobility transistor devices. Please refer to FIG. 1, FIG. 7, and the relevant contents mentioned above. Similar to the fabrication of D-mode HEMT devices, when fabricating E-mode HEMT devices, a process is conducted where a nucleation layer 110, a buffer layer 120, a channel layer 130, and a semiconductor barrier layer 140 are sequentially formed on a substrate 100. The materials and fabrication methods for the substrate 100, nucleation layer 110, buffer layer 120, channel layer 130, and semiconductor barrier layer 140 in this embodiment can be referred to the disclosed contents above. The details will not be reiterated here. Subsequently, a p-type doped semiconductor layer is formed on the semiconductor barrier layer 140. In this embodiment, the p-type doped semiconductor layer is a p-type doped gallium nitride layer 190. Furthermore, doping with p-type impurities is carried out on the gallium nitride layer, for example, using magnesium, calcium, zinc, beryllium, carbon, or combinations thereof. In specific embodiments, the thickness of the p-type doped gallium nitride layer 190 ranges from about 1 nm to 100 nm.

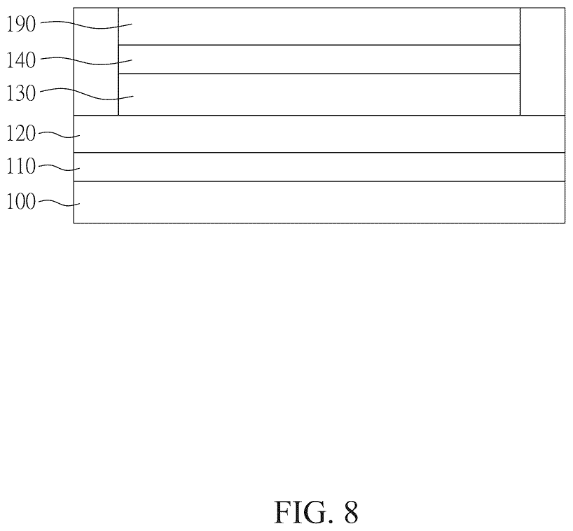

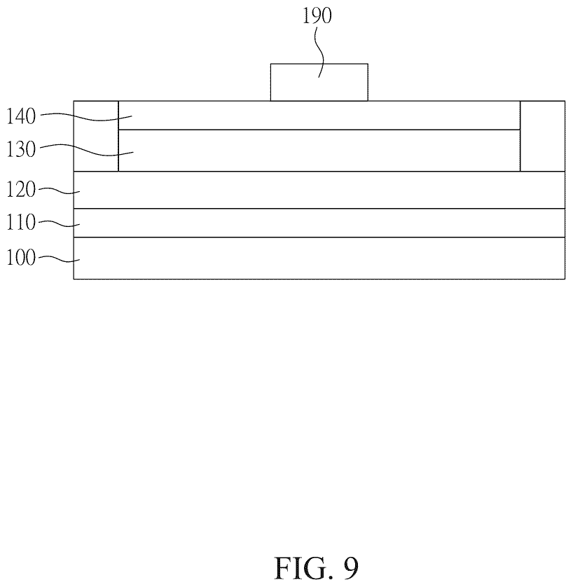

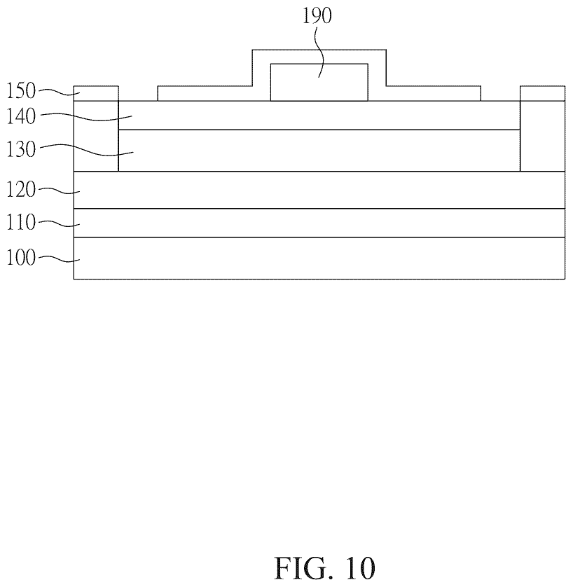

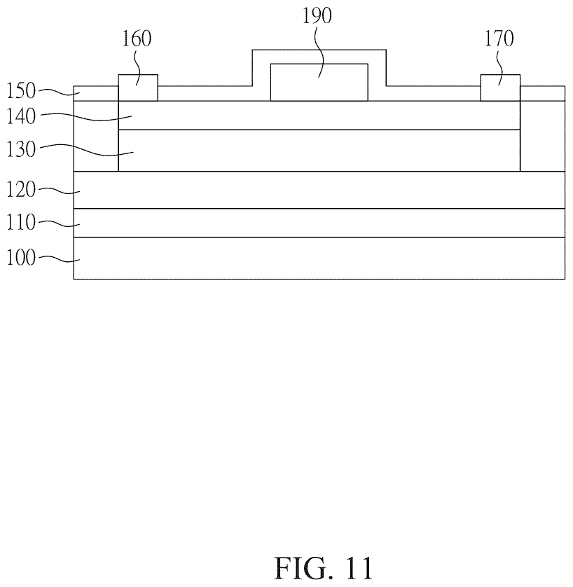

Please refer to FIG. 8. An isolation insulation process between the active region and the non-active region of the device is performed. Similar to the previous embodiment, in this embodiment, an ion implantation process is used for device isolation treatment, utilizing ion implantation of nitrogen ions, argon ions, boron ions, oxygen ions, arsenic ions, and other ions. Next, please refer to FIG. 9. An etching process is performed to define the p-type doped gallium nitride layer 190 of the gate structure. Referring to FIG. 10, similar to the previous embodiment, an insulation protective layer 150 is formed above the semiconductor barrier layer 140 to define the source and drain regions. The material composition and fabrication method of the insulation protective layer 150 in this embodiment can refer to the disclosed contents above and will not be reiterated here. Then, please refer to FIG. 11, where the source electrode 160 and the drain electrode 170 in ohmic contact with the semiconductor barrier layer 140 are formed above the source and drain regions of the semiconductor barrier layer 140. The specific material composition and fabrication method for forming the source electrode and drain electrode can refer to the disclosed contents above and will not be reiterated here.

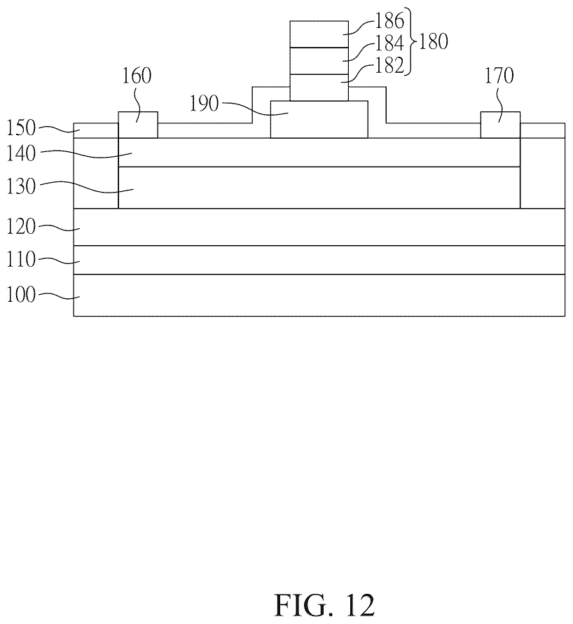

Please refer to FIG. 12, where the gate electrode region is defined on the insulation protective layer 150 by exposing a portion of the p-type doped gallium nitride layer 190. A metal evaporation process is then performed in this gate electrode region to form the gate electrode 180 on top of the exposed portion of the p-type doped gallium nitride layer 190. To solve the issue of gate hard breakdown caused by high gate leakage current in conventional high electron mobility transistor (HEMT) devices, this embodiment of the present also applies an innovative gate structure with dual barrier layers to suppress the gate leakage current. Specifically, similar to the previous embodiments, the gate electrode 180 of the present invention comprises a first gate barrier layer 182 and a second gate barrier layer 184. The first gate barrier layer 182 is disposed above the exposed portion of the p-type doped gallium nitride layer 190, while the second gate barrier layer 184 is disposed above the first gate barrier layer 182. Moreover, the work function of the first gate barrier layer 182 is greater than that of the p-type doped gallium nitride layer 190, and the work function of the second gate barrier layer 184 is greater than that of the first gate barrier layer 182. In specific embodiments, the first gate barrier layer 182 can be a conductive metal compound or a conductive ceramic, with a work function of not less than 4 eV, but not limited thereto. The conductive metal compound may be selected from the group consisting of titanium nitride, tantalum nitride, and tungsten nitride. The second gate barrier layer 184 may be a conductive material with a higher work function, and the work function of this conductive material is not less than 5 eV, but not limited thereto. The conductive material may be selected from the group consisting of nickel, platinum, tungsten, and tungsten nitride. Additionally, the gate electrode 180 further includes a low-resistance metal layer 186, disposed above the second gate barrier layer 184. This low-resistance metal layer can be selected from the group consisting of aluminum, platinum, titanium, nickel, tungsten, copper, palladium, gold, and combinations thereof.

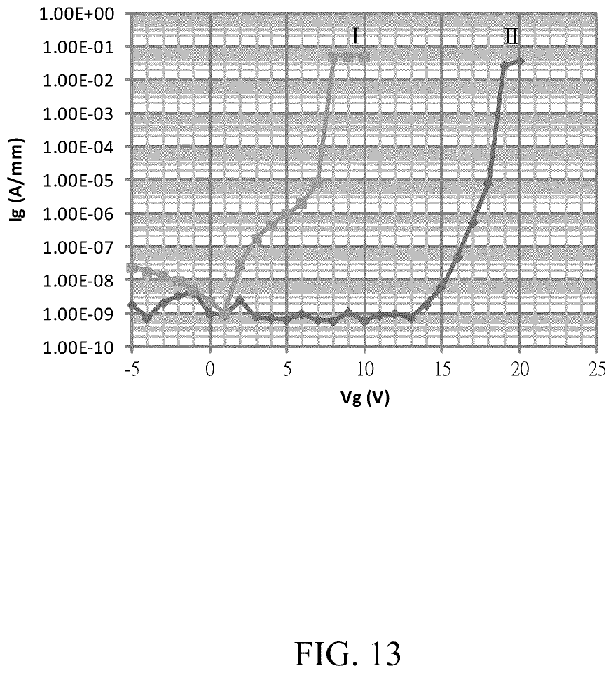

Please refer to FIG. 13, which illustrates a comparison curve of the gate current versus voltage relationship between the p-type doped gallium nitride-enhanced mode high electron mobility transistor (pGaN E-mode HEMT) of the present invention and a conventional pGaN E-mode HEMT device. In FIG. 13, the curve connecting the square markers represents the current-voltage curve (Curve I) of the conventional pGaN E-mode HEMT device, while the curve connecting the diamond markers represents the current-voltage curve (Curve II) of the pGaN E-mode HEMT device of the present invention. Comparing Curves I and II in FIG. 13, it can be observed that the gate voltage of the conventional pGaN E-mode HEMT device experiences gate hard breakdown due to high gate leakage current between 7V and 10V. Thereby, the conventional device is limited by its operating range between 0V and 6V. In contrast, the present invention utilizes the difference in work functions of the dual barrier layers in the gate structure to suppress the gate leakage current. As a result, the gate voltage of the pGaN E-mode HEMT device of the present invention can be increased from 7V to approximately 19V. The operational voltage range of the high electron mobility transistor device of the present invention will be significantly increased.

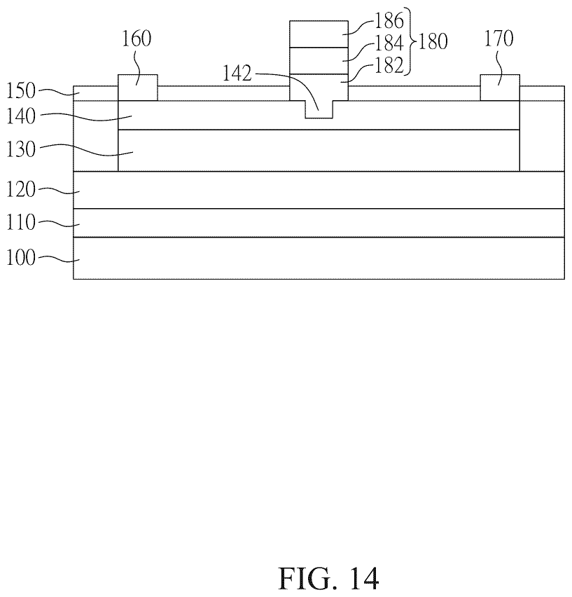

It should be noted that the above is just one embodiment of the present invention, which relates to a normally-off high-electron-mobility transistor (HEMT). The technical features of the present invention, which disclose a dual-barrier gate structure, can also be applied to other normally-off HEMT devices. Please refer to FIG. 14, which shows the recess gate structure of a normally-off HEMT device. Specifically, the gate electrode 180 also features a dual-barrier gate structure with a first gate barrier layer 182 and a second gate barrier layer 184. However, unlike the previous embodiment, there is no p-type doped gallium nitride layer 190 below the gate electrode 180. Instead, there is a recess structure 142 in the semiconductor barrier layer 140 below the gate electrode 180, and the recess structure 142 is filled with the first gate barrier layer 182 to enhance the gate's control over the electron channel. In this embodiment, the dual-barrier gate structure with the recess structure can also utilize the feature of the difference in the work functions of the dual-layer barrier materials in the gate structure to achieve the effect of suppressing gate leakage current.

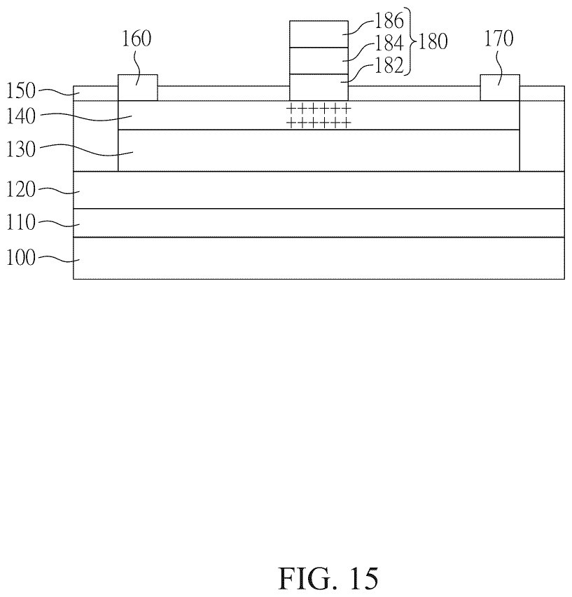

On the other hand, please refer to FIG. 15, which illustrates another type of normally-off HEMT device employing the technical features of the present invention. Specifically, similar to the embodiments shown above, in the HEMT device of the embodiment depicted in FIG. 15, the gate electrode 180 also features a dual-barrier gate structure with a first gate barrier layer 182 and a second gate barrier layer 184. Additionally, in the portion of the semiconductor barrier layer (i.e., the aluminum gallium nitride layer) 140 below the gate electrode 180, fluorine ion dopants are introduced to modify the band bending between the semiconductor barrier layer and the channel layer for affecting and adjusting the required gate voltage for electron channel activation correspondingly. Furthermore, the difference in the work functions of the dual-layer gate barriers is utilized to achieve the desired effect of suppressing gate leakage current in accordance with the present invention.

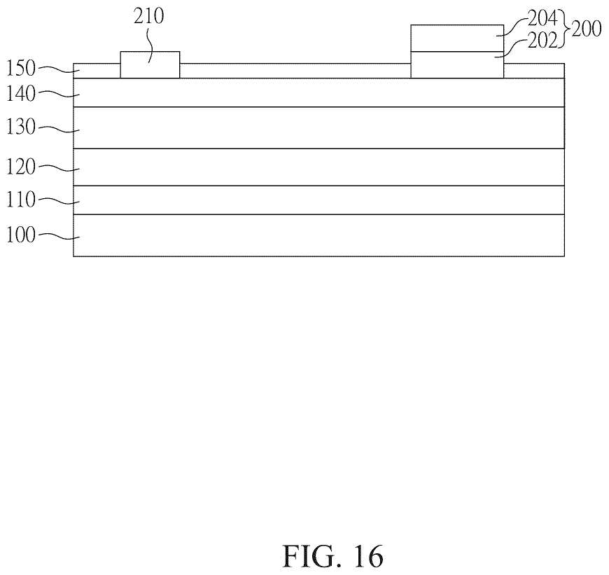

The technical features of the present invention, employing multi-stage barrier layers to suppress leakage current, can also be widely applied to Schottky barrier diodes (SBDs), as explained below. Please refer to FIG. 16, which illustrates one embodiment of a D-mode SBD device with a dual-barrier layer structure according to the present invention. The structure, from bottom to top, comprises a substrate 100, a nucleation layer 110, a buffer layer 120, a channel layer 130, and a semiconductor barrier layer 140. The material composition and fabrication methods of the substrate 100, nucleation layer 110, buffer layer 120, channel layer 130, and semiconductor barrier layer 140 in this embodiment can be referred to the disclosed above and will not be repeated here. Taking aluminum gallium nitride layer as an example for the semiconductor barrier layer 140, an anode electrode 200 and a cathode electrode 210 are respectively disposed at two opposing ends on top of the semiconductor barrier layer 140. The anode electrode 200 comprises a first anode barrier layer 202 and a second anode barrier layer 204. The first anode barrier layer 202 is disposed between the semiconductor barrier layer 140 and the second anode barrier layer 204. The work function of the first anode barrier layer 202 is greater than that of the semiconductor barrier layer 140 and less than that of the second anode barrier layer 204. In specific embodiments, the first anode barrier layer 202 is a conductive metal compound with a work function not less than 4 eV. The conductive metal compound is selected from the group consisting of titanium nitride, tantalum nitride, and tungsten nitride. Additionally, the second anode barrier layer 204 is a conductive material with a work function not less than 5 eV and is selected from the group consisting of among nickel, platinum, tungsten, and tungsten nitride. The material for the cathode electrode 210 can be selected from the group consisting of titanium, aluminum, nickel, molybdenum, titanium nitride, gold and combinations thereof.

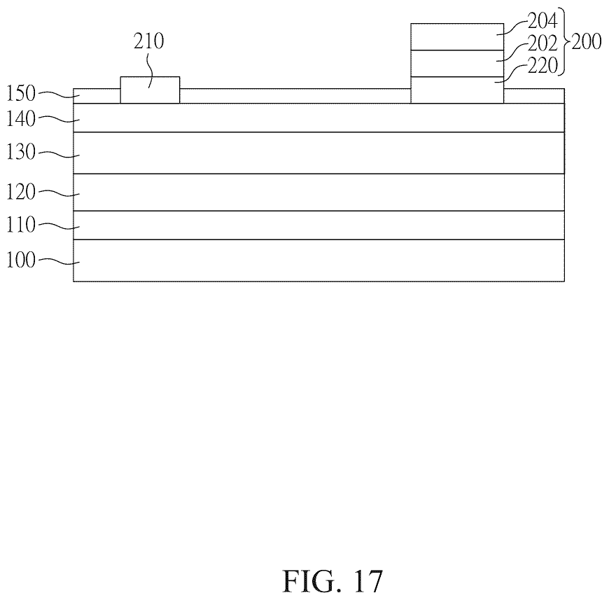

Please refer to FIG. 17, which illustrates one embodiment of an E-mode SBD device with a dual-barrier layer structure according to the present invention. This embodiment is similar to FIG. 16 but with some differences. This E-mode SBD device further comprises a P-type doped gallium nitride layer 220, disposed between the semiconductor barrier layer 140 (i.e., aluminum gallium nitride layer) and the first anode barrier layer 202. The work function of the first anode barrier layer 202 is greater than that of the P-type doped gallium nitride layer 220.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A semiconductor structure, comprising:
a substrate;
a semiconductor barrier layer, disposed above the substrate; and
a gate electrode, disposed above the semiconductor barrier layer, and having a first gate barrier layer and a second gate barrier layer,
wherein the first gate barrier layer is disposed between the semiconductor barrier layer and the second gate barrier layer, and a work function of the first gate barrier layer is greater than that of the semiconductor barrier layer, and a work function of the second gate barrier layer is greater than that of the first gate barrier layer.

2. The semiconductor structure of claim 1, wherein the first gate barrier layer is a conductive metal compound, and a work function of the conductive metal compound is not less than 4 eV.

3. The semiconductor structure of claim 2, wherein the conductive metal compound is selected from the group consisting of titanium nitride, tantalum nitride, and tungsten nitride.

4. The semiconductor structure of claim 2, wherein the second gate barrier layer is a conductive material, and a work function of the conductive material is not less than 5 eV.

5. The semiconductor structure of claim 4, wherein the conductive material is selected from the group consisting of nickel, platinum, tungsten, and tungsten nitride.

6. The semiconductor structure of claim 1, further comprising a source electrode and a drain electrode, respectively disposed above the semiconductor barrier layer.

7. The semiconductor structure of claim 6, wherein the source electrode and the drain electrode are selected from the group consisting of titanium, aluminum, nickel, molybdenum, titanium nitride, gold and their combinations.

8. The semiconductor structure of claim 1, wherein the semiconductor barrier layer is an aluminum gallium nitride layer.

9. The semiconductor structure of claim 8, further comprising a gallium nitride layer, wherein the aluminum gallium nitride layer is disposed above the gallium nitride layer.

10. The semiconductor structure of claim 8, further comprising a P-type doped gallium nitride layer, wherein the P-type doped gallium nitride layer is disposed between the aluminum gallium nitride layer and the first gate barrier layer, and the work function of the first gate barrier layer is greater than a work function of the P-type doped gallium nitride layer.

11. The semiconductor structure of claim 1, wherein the semiconductor barrier layer below the gate electrode further includes a recessed structure, and the recessed structure is filled with the first gate barrier layer.

12. The semiconductor structure of claim 8, wherein a portion of the aluminum gallium nitride layer below the gate electrode is doped by fluorine ions.

13. The semiconductor structure of claim 1, wherein the gate electrode further comprises a low-resistance metal layer, disposed above the second gate barrier layer.

14. The semiconductor structure of claim 13, wherein the low-resistance metal layer is selected from the group consisting of aluminum, platinum, titanium, nickel, tungsten, copper, palladium, gold and their combinations.

15. A semiconductor structure, comprising:
a substrate;
a semiconductor barrier layer, disposed above the substrate; and
an anode electrode and a cathode electrode, respectively disposed at two opposite ends above the semiconductor barrier layer, wherein the anode electrode has a first anode barrier layer and a second anode barrier layer,
wherein the first anode barrier layer is disposed between the semiconductor barrier layer and the second anode barrier layer, and a work function of the first anode barrier layer is greater than that of the semiconductor barrier layer, and a work function of the second anode barrier layer is greater than that of the first anode barrier layers.

16. The semiconductor structure of claim 15, wherein the first anode barrier layer is a conductive metal compound, and a work function of the conductive metal compound is not less than 4 eV.

17. The semiconductor structure of claim 16, wherein the conductive metal compound is selected from the group consisting of titanium nitride, tantalum nitride, and tungsten nitride.

18. The semiconductor structure of claim 16, wherein the second anode barrier layer is a conductive material, and a work function of the conductive material is not less than 5 eV.

19. The semiconductor structure of claim 18, wherein the conductive material is selected from the group consisting of nickel, platinum, tungsten, and tungsten nitride.

20. The semiconductor structure of claim 18, wherein the semiconductor barrier layer is an aluminum gallium nitride layer, and the semiconductor structure further comprises a P-type doped gallium nitride layer, disposed between the aluminum gallium nitride layer and the first anode barrier layer, and the work function of the first anode barrier layer is greater than a work function of the P-type doped gallium nitride layer.
